(19) United States
(12) Patent Application Publication
(10) Pub. No.: US 2026/0058440 A1
(43) Pub. Date: Feb. 26, 2026

(54) LIGHT EMITTING DEVICE AND OPTICAL RANGING MODULE

(71) Applicant: Newmax Technology Co., Ltd., Taichung City (TW)

(72) Inventor: Tsung-Chi TSAI, Taichung City (TW)

(21) Appl. No.: 18/927,749

(22) Filed: Oct. 25, 2024

(30) Foreign Application Priority Data
Aug. 23, 2024 (TW) 113131779

(51) Int. Cl. H01S 5/183; G01S 7/481

(52) U.S. Cl. CPC H01S 5/18388; G01S 7/4814

(57) ABSTRACT

A light emitting device includes: a first base; a first outer cap, which is disposed on the first base and includes a first opening region; a first optical lens, which is disposed in the first opening region and has a source-side surface and an object-side surface, wherein the source-side surface includes a plurality of spherical surface bodies; and an infrared light source, which is disposed on the first base, wherein the light of the infrared light source passes through the spherical surface bodies on the source-side surface of the first optical lens, so as to cause the light to produce a predetermined shape.

This application claims the benefit of Taiwan Patent Application No. 113131779, filed on Aug. 23, 2024, which is hereby incorporated by reference for all purposes as if fully set forth herein.

### BACKGROUND

### Technical Field

The present disclosure relates to a light emitting device, and in particular to an optical ranging module including a light emitting device.

### Related Art

Today's smart phones, tablets or other handheld devices are equipped with TOF (Time of Flight) ranging modules to achieve various functions such as gesture detecting function, three-dimensional (3D) imaging function, or camera focusing function. During operation, the TOF ranging module transmits near-infrared light into an object in the scene and uses the time-of-flight information of the light to measure the distance of the object in the scene. The advantages of the TOF ranging module are small calculation of the depth information, strong anti-interference, and long measurement range, so the TOF ranging module has gradually become popular.

The TOF ranging module in the prior art usually includes two optical lenses. The first optical lens is a light emitting (TX) optical lens. When the first optical lens receives light from an infrared light source, the light is transmitted to the object to be measured. The second optical lens is a light receiving (RX) optical lens. When the second optical lens receives the light reflected back by the object to be measured, and the light is then transmitted to the photosensitive element. Therefore, the design of the TOF ranging module for mobile phones must have, first, fast focusing and ranging functions; second, the compensating function for the attenuation of relative illumination of an imaging lens module (including RX optical lens).

Thus, a light emitting device and an optical ranging module need to be provided for meeting previous requirements.

### SUMMARY

An objective of the present disclosure is to provide an infrared light source of a light emitting device of an optical ranging module, whose light passes through spherical surface bodies on a source-side surface of an optical lens, so as to cause the light to produce a predetermined shape.

To achieve the above objective, the present disclosure provides a light emitting device, defined with a source side and an object sid and comprising: a first base; a first outer cap disposed on the first base and comprising es a first opening region; a first optical lens disposed in the first opening region and having a source-side surface and an object-side surface, wherein the source-side surface includes a plurality of spherical surface bodies; and an infrared light source disposed on the first base, wherein light of the infrared light source passes through the spherical surface bodies on the source-side surface of the first optical lens, so as to cause the light to produce a predetermined shape; wherein each spherical surface body has a maximum thickness H along an X-axis, and a width D along an Y-axis, and the following condition is satisfied: D=3H; and wherein the surface type of each spherical surface body is a quadratic surface, a vertex curvature is c, a curvature radius is r=√(X∧2+Y∧2), a conic constant is k, and the following formula for spherical surface is satisfied: Z=cr∧2/{1+√[1−(1+k)c∧2r∧2]}, that is

$$z = \frac{{cr}^{2}}{1 + \sqrt{1 - ( 1 + k ) {c}^{2} {r}^{2}}} .$$

The present disclosure further provides an optical ranging module, comprising: a light emitting device, defined with a source side and an object sid and comprising: a first base; a first outer cap disposed on the first base and comprising es a first opening region; a first optical lens disposed in the first opening region and having a source-side surface and an object-side surface, wherein the source-side surface includes a plurality of spherical surface bodies; and an infrared light source disposed on the first base, wherein light of the infrared light source passes through the spherical surface bodies on the source-side surface of the first optical lens, so as to cause the light to produce a predetermined shape; and a light receiving device comprising a second base, a second outer cap, a second optical lens and a photosensitive element, wherein the second outer cap is disposed on the second base and comprises a second opening region, the second optical lens is disposed in the second opening region, and the photosensitive element is disposed on the second base; wherein the first base and the second base are integrally formed, and the first outer cap and the second outer cap are integrally formed; wherein each spherical surface body has a maximum thickness H along an X-axis, and a width D along an Y-axis, and the following condition is satisfied: D=3H; and wherein the surface type of each spherical surface body is a quadratic surface, a vertex curvature is c, a curvature radius √(X∧2+Y∧2) is r, a conic constant is k, and the following formula for spherical surface is satisfied: Z=cr∧2/{1√[1−(1+k)c∧2r∧2]}, that is.

$$z = \frac{{cr}^{2}}{1 + \sqrt{1 - ( 1 + k ) {c}^{2} {r}^{2}}} .$$

According to the light emitting device of the optical ranging module of the present disclosure, the source-side surface of the first optical lens is designed with a plurality of spherical surface bodies. According to a designated infrared light source, the light can pass through the spherical surface bodies of the first optical lens, a predetermined shape of light will be produced. The radiation intensity distribution and light shape of the light emitting device can be simulated by the Lighttools software, which shows that the present disclosure can compensate for the lack of relative illumination of the imaging lens module (i.e., the light receiving device), balance the system signal-to-noise ratio, reduce effects of the range of depth, and ensure that the optical ranging module can have the quality and performance of fast focusing and ranging.

### BRIEF DESCRIPTION OF THE DRAWINGS

FIG. 1 is a schematic sectional view of an optical ranging module according to an embodiment of the present disclosure.

FIG. 2 is a schematic sectional view of a light emitting device according to an embodiment of the present disclosure.

FIG. 3a to FIG. 3e are schematic perspective views of spherical surface bodies according to five aspects of an embodiment of the present disclosure.

FIG. 4 is a schematic plan view of a plurality of spherical surface bodies according to an embodiment of the present disclosure.

FIG. 5 is a schematic sectional view of a spherical surface body according to an embodiment of the present disclosure.

FIG. 6a and FIG. 6b are 2D light intensity diagrams of FOI (H&V axis) of the light emitting device simulated by Lighttools software according to the main embodiment of the present disclosure.

FIG. 7a and FIG. 7b are 3D light intensity diagrams of FOI (H&V axis) of the light emitting device simulated by Lighttools software according to the main embodiment of the present disclosure.

FIG. 8a and FIG. 8b are 2D light intensity diagrams of FOI (Diagonal axis) of the light emitting device simulated by the Lighttools software according to the main embodiment of the present disclosure.

FIG. 9a and FIG. 9b are 3D light intensity diagrams of FOI (Diagonal axis) of the light emitting device simulated by the Lighttools software according to the main embodiment of the present disclosure.

FIG. 10a and FIG. 10b are 2D light intensity diagrams of FOI (H&V axis) simulated by the Lighttools software of the light emitting device according to the first embodiment of the present disclosure.

FIG. 11a and FIG. 11b are 3D light intensity diagrams of FOI (H&V axis) simulated by Lighttools software of the light emitting device according to the first embodiment of the present disclosure.

FIG. 12a and FIG. 12b are 2D light intensity diagrams of FOI (Diagonal axis) simulated by the Lighttools software of the light emitting device according to the first embodiment of the present disclosure.

FIG. 13a and FIG. 13b are 3D light intensity diagrams of FOI (Diagonal axis) simulated by the Lighttools software of the light emitting device according to the first Embodiment of the present disclosure.

FIG. 14a and FIG. 14b are 2D light intensity diagrams of FOI (H&V axis) simulated by the Lighttools software of the light emitting device according to the second embodiment of the present disclosure.

FIG. 15a and FIG. 15b are 3D light intensity diagrams of FOI (H&V axis) simulated by Lighttools software of the light emitting device according to the second embodiment of the present disclosure.

FIG. 16a and FIG. 16b are 2D light intensity diagrams of FOI (Diagonal axis) simulated by the Lighttools software of the light emitting device according to the second embodiment of the present disclosure.

FIG. 17a and FIG. 17b are 3D light intensity diagrams of FOI (Diagonal axis) simulated by the Lighttools software of the light emitting device according to the second Embodiment of the present disclosure.

FIG. 18 to FIG. 26 are nine lookup tables (NO. 1 to NO. 9) based on the width D value of a plurality of spherical surface bodies of the present disclosure.

FIG. 27 is a schematic diagram showing that spherical surface bodies are arranged in an array manner of a single area with an irregular Gaussian distribution according to the width D of a lookup table of the present disclosure.

FIG. 28 is a schematic diagram showing that spherical surface bodies the spherical surface bodies are arranged in an array manner of a 3×3 nine-area with an irregular Gaussian distribution according to the width D of lookup tables of the present disclosure.

### DETAILED DESCRIPTION

To make the foregoing objectives, characteristics and features of the present disclosure more comprehensible, preferred embodiments of the present disclosure are described in detail below with reference to the accompanying drawings.

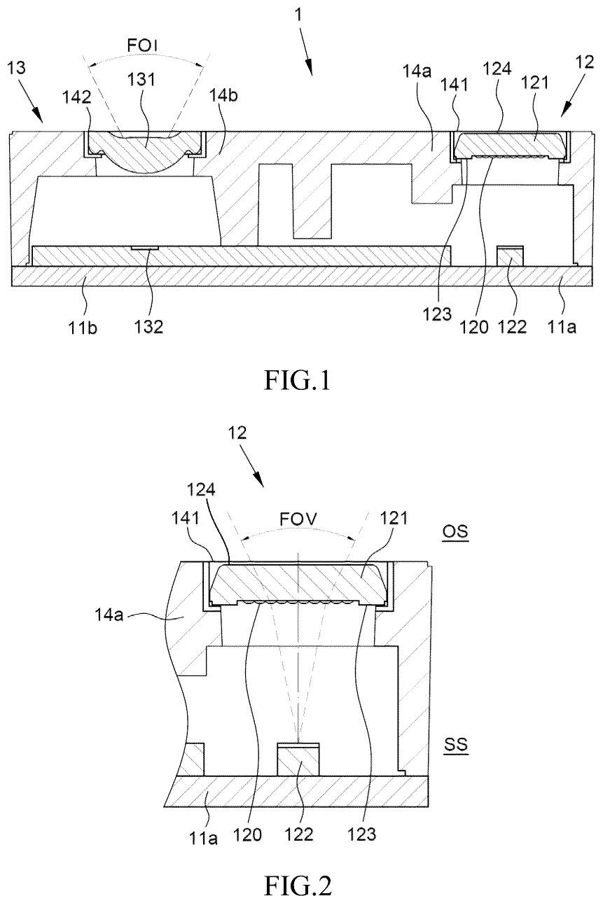

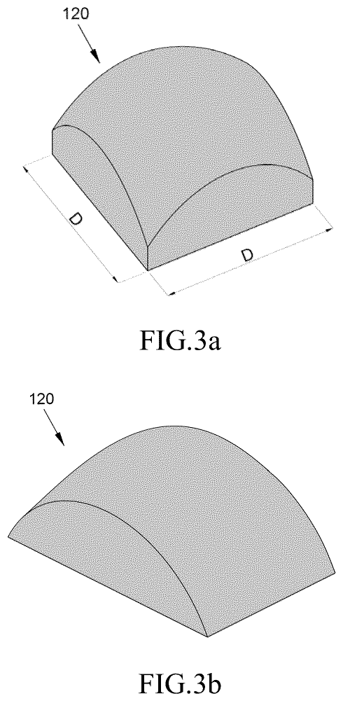

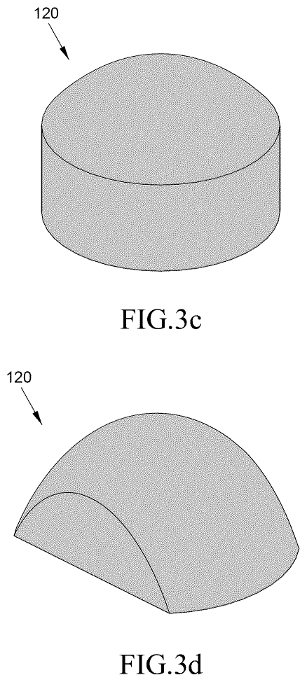

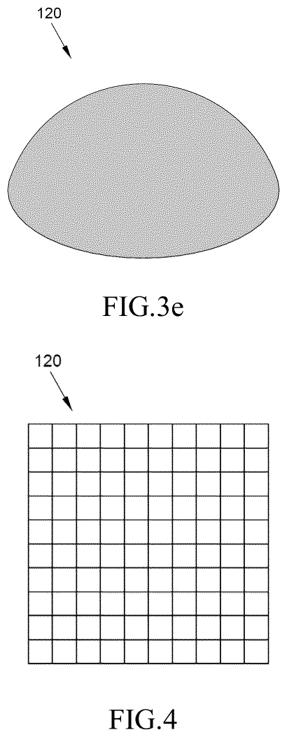

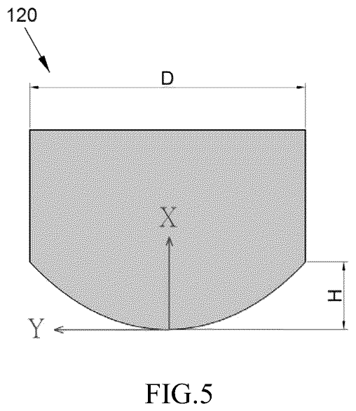

FIG. 1 is a schematic sectional view of an optical ranging module according to an embodiment of the present disclosure. Referring to FIG. 1, the optical ranging module 1 includes: a light emitting device (TX device) 12 and a light receiving device (RX device). FIG. 2 is a schematic sectional view of a light emitting device according to an embodiment of the present disclosure. Referring to FIG. 1 and FIG. 2, the light emitting device 12 (which can be called as an illumination device) is defined with a source side SS and an object side OS, and includes a first base 11a, a first outer cap 14a, a first optical lens (which can be called as TX optical lens) 121 and an infrared light source 122. The first outer cap 14a is disposed on the first base 11a and includes a first opening region 141. The first optical lens 121 is disposed in the first opening region 141 and has a source-side surface 123 and an object-side surface 124, wherein the source side surface 123 includes a plurality of spherical surface bodies 120 (which can be called as ball bags). FIG. 3a to FIG. 3e are schematic perspective views of a spherical surface bodies according to five aspects of an embodiment of the present disclosure. FIG. 4 is a schematic plan view of a plurality of spherical surface bodies according to an embodiment of the present disclosure. Referring to FIG. 2, FIG. 3a and FIG. 4, the width D of the spherical surface body 120 can be between 0.034 and 0.042 mm, and the spherical surface bodies 120 are arranged on the source-side surface 123 in an array manner. The density of the spherical surface bodies 120 is that there are N spherical surface bodies 120 in the effective area of 1.0 mm*1.0 mm, N≤625. The infrared light source 122 is disposed on the first base 11a, wherein the light of the infrared light source 122 passes through the spherical surface bodies 120 of the source-side surface 123 of the first optical lens 121, so as to cause the light to produce a predetermined shape. For example, the first optical lens 121 can be made of plastic material, and the refractive index (Nd) of the first optical lens 121 is between 1.52 and 1.68.

Referring to FIG. 1 again, the light receiving device 13 (which can be called an imaging device) includes a second base 11b, a second outer cap 14b, a second optical lens (which can called as RX optical lens) 131 and a photosensitive element 132. The second outer cap 14b is disposed on the second base 11b and includes a second opening region 142. The second optical lens 131 is disposed in the second opening region 142, and the photosensitive element 132 is disposed on the second base 11b. The first base 11a and the second base 11b are integrally formed, and the first outer cap 14a and the second outer cap 14b are integrally formed. For example, the second optical lens 131 can be a plane lens made of plastic material.

The optical ranging module 1 of the present disclosure can be a TOF ranging module, and includes: the infrared light source 122, such as an infrared vertical cavity surface emitting laser (VCSEL); the photosensitive element 132, such as light sensors or Single Photon Avalanche Diode (SPAD); and the time to digital converter (TDC). The SPAD is a photo detection avalanche diode with single-photon detection capability, which can generate current as long as there is a weak light signal. The VCSEL emits infrared pulse light to an object to be measured in the scene, the SPAD receives the infrared pulse light reflected from the object, and the TDC records the time interval between the emitted light and the received light (that is, the flight time), and uses the flight time to calculate the distance of the object. Therefore, the accuracy of the time interval between the emitted light and the received light is directly related to the accuracy of the distance of the object. In other words, it is necessary to determine the time when the VCSEL emits infrared pulse light, and the time when the SPAD receives the infrared pulse light reflected from the object. The overall light process is the VCSEL light source→TX optical lens (the first optical lens)→the object→RX optical lens (the second optical lens)→the SPAD light sensor.

For example, a structure of the light-emitting device of the present disclosure can be used in a TOF ranging module of a mobile phone, and is designed to enable fast focusing and ranging. The light emitting device of the present disclosure is suitable for an illuminating lens module including: a plastic lens, a fixed base and an infrared light source. The light emitting device of the present disclosure is a lighting device applied to the illuminating lens module, which further includes: a driver that drives the light source at a high modulation frequency and a diffuser that projects the light beam from the light source to the designed illumination field of view (FOI) (i.e., the spherical surface bodies of the source-side surface of the first optical lens). According to an illumination profile shape within the illumination field of view (FOI), the common radiation intensity distribution is M-shaped and has a profile that changes with cos-n (Θ) to compensate for the attenuation of the relative illumination of the imaging lens module (including RX optical lenses). The infrared light source generates constant optical power and distributes it into the 3D space within the illumination field of view (FOI) formed by the diffuser. As the illumination field of view (FOI) increases, the energy per sphericity (sr), i.e., radiant intensity (light intensity) (w/sr) will decrease. The balance between the illumination field of view (FOI) and the radiant intensity affects the signal-to-noise ratio of the system, and further the depth range is affected. The wavelength of the infrared light source is: 940±10 nm. The shape design and light shape of the diffuser (i.e., the spherical surface bodies) need to match the aspect ratio of the imaging lens module. For example, the top view of the spherical surface body can be square, rectangular, circular or elliptical, or the spherical surface body can be hemispherical, as shown in FIG. 3a to FIG. 3e. The light emitting device of the present disclosure has a single engineered diffuser (i.e., the spherical surface bodies) with specific divergence and optical parameters to achieve the required illumination field of view (FOI), such as light intensity angle of FOI (H&V axis): 44deg. and light intensity angle of FOI (Diagonal axis): 65deg. A structure of the spherical surface body of the diffuser is: plano-convex lens.

FIG. 5 is a schematic sectional view of a spherical surface body according to an embodiment of the present disclosure. Each spherical surface body 120 has a maximum thickness H along an X-axis, and a width D along an Y-axis, and the following condition is satisfied: D=3H; and the surface type of each spherical surface body 120 is a quadratic surface, a vertex curvature is c, a curvature radius is r=√(X∧2+Y∧2), a conic constant is k, and the following formula for spherical surface is satisfied: Z=cr∧2/{1√[1−(1+k)c∧2r∧2]}, that is

$$z = \frac{{cr}^{2}}{1 + \sqrt{1 - ( 1 + k ) {c}^{2} {r}^{2}}} .$$

wherein the vertex curvature of the spherical surface body is between 45 and 80, and the conic constant of the spherical surface body is between −1.0 and −2.5.

According to the light emitting device of the optical ranging module of the present disclosure, the source-side surface of the first optical lens is designed with a plurality of spherical surface bodies. According to a designated infrared light source, the light can pass through the spherical surface bodies of the first optical lens, a predetermined shape of light will be produced. The radiation intensity distribution and light shape of the light emitting device can be simulated by the Lighttools software, which shows that the present disclosure can compensate for the lack of relative illumination of the imaging lens module (i.e., the light receiving device), balance the system signal-to-noise ratio, reduce effects of the range of depth, and ensure that the optical ranging module can have the quality and performance of fast focusing and ranging.

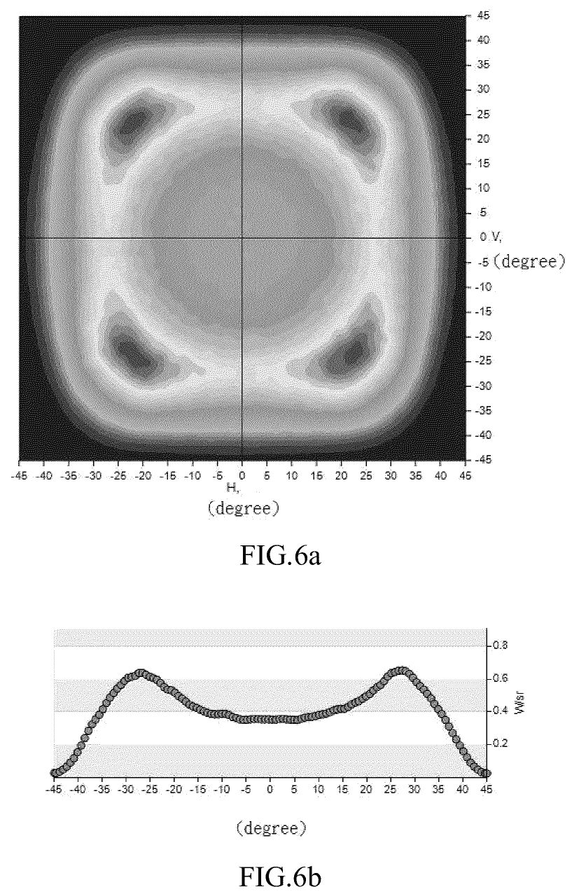

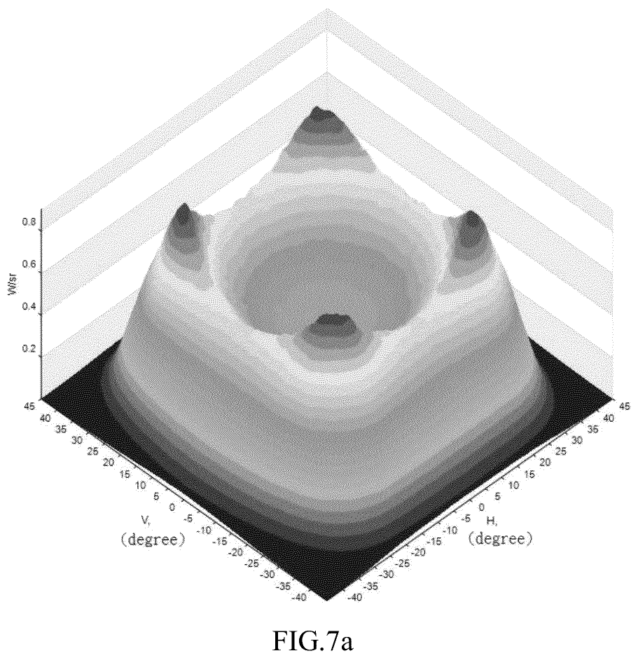

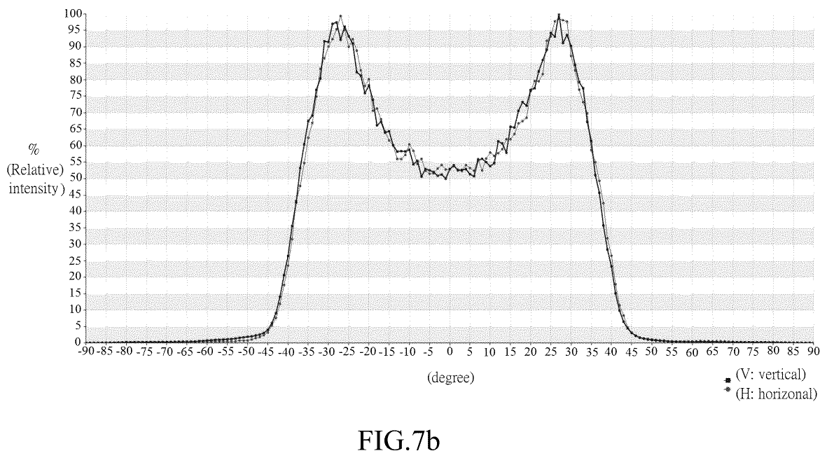

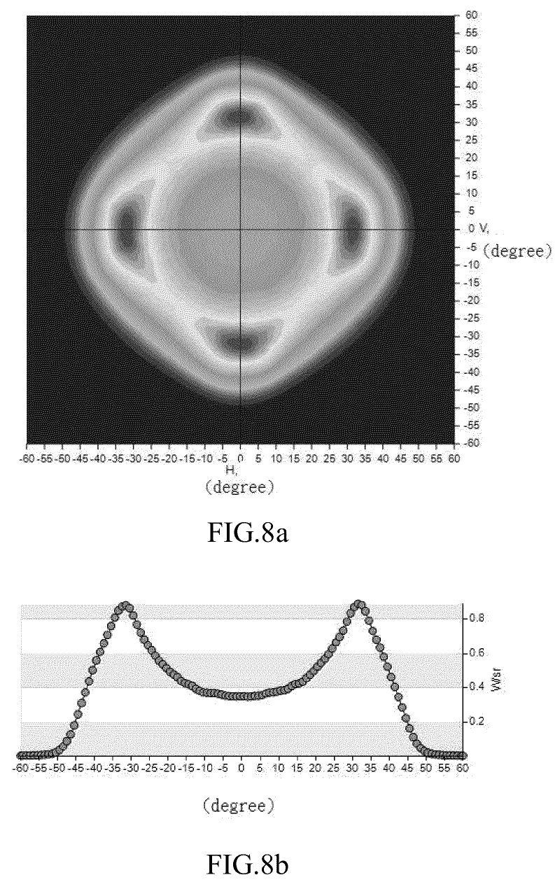

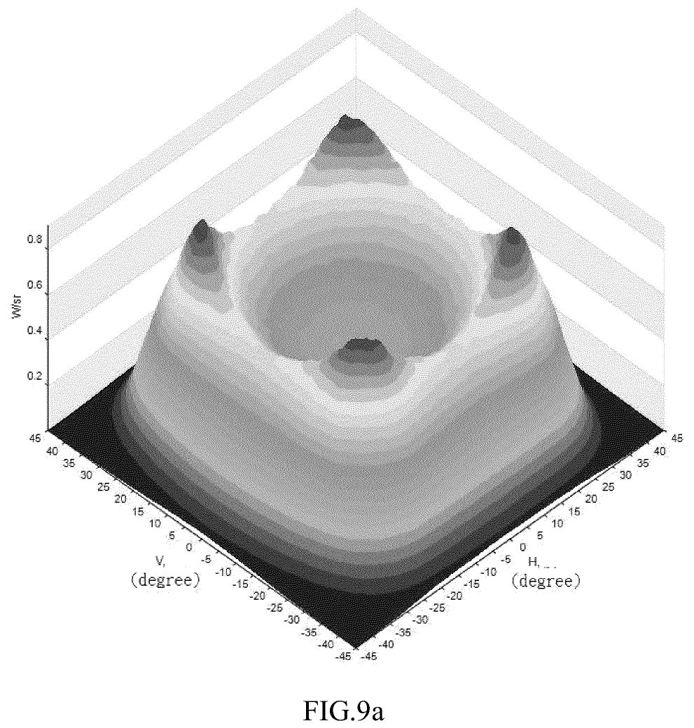

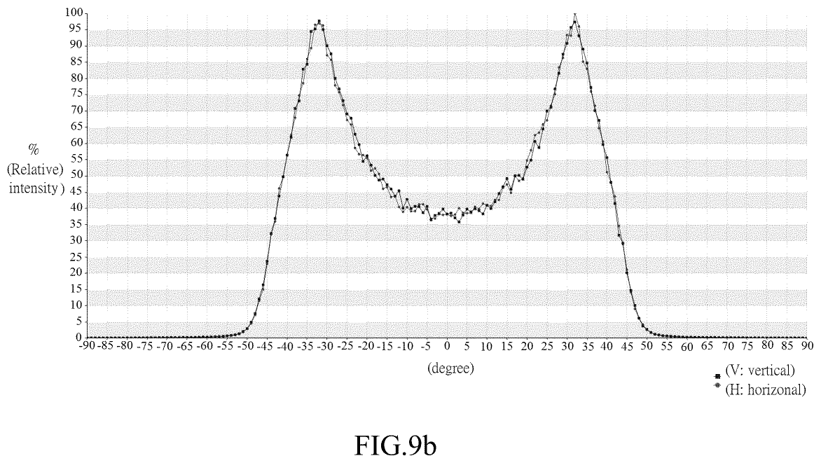

According to the light emitting device in the main embodiment of the present disclosure: Lighttools software is used to simulate the beam angle & light shape; parameter conditions are: (a) curvature: 68, (b) curvature coefficient (k): −1.30, (c) illumination profile: square, (d) light intensity angle of FOI (H&V axis): 44deg, (e) light intensity angle of FOI (Diagonal axis): 65deg, (f) working distance=1.35 mm, (g) lens FOV=65deg (maximum beam angle), (h) the width of the spherical surface body is D, wherein D=0.038 mm. FIG. 6a and FIG. 6b are 2D light intensity diagrams of FOI (H&V axis) of the light emitting device simulated by Lighttools software according to the main embodiment of the present disclosure. FIG. 7a and FIG. 7b are 3D light intensity diagrams of FOI (H&V axis) of the light emitting device simulated by Lighttools software according to the main embodiment of the present disclosure. FIG. 8a and FIG. 8b are 2D light intensity diagrams of FOI (Diagonal axis) of the light emitting device simulated by the Lighttools software according to the main embodiment of the present disclosure. FIG. 9a and FIG. 9b are 3D light intensity diagrams of FOI (Diagonal axis) of the light emitting device simulated by the Lighttools software according to the main embodiment of the present disclosure.

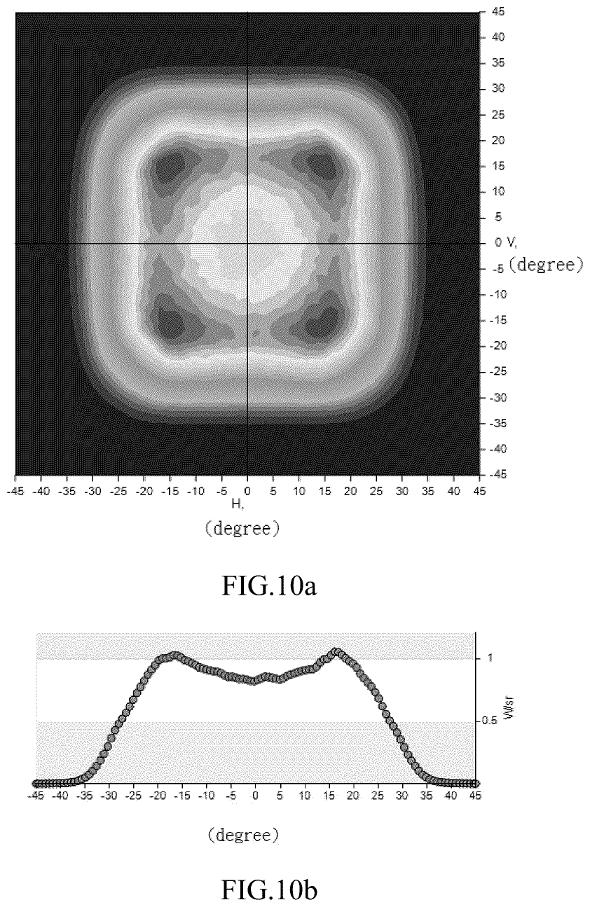

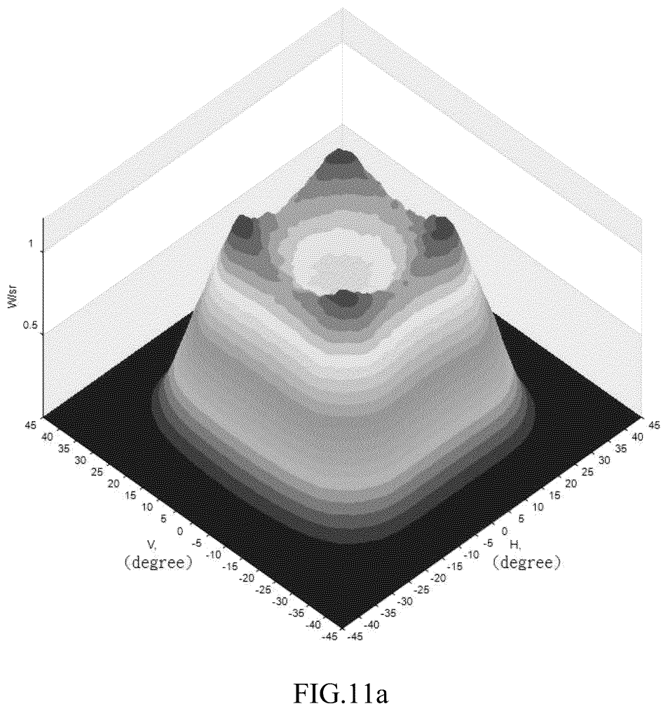

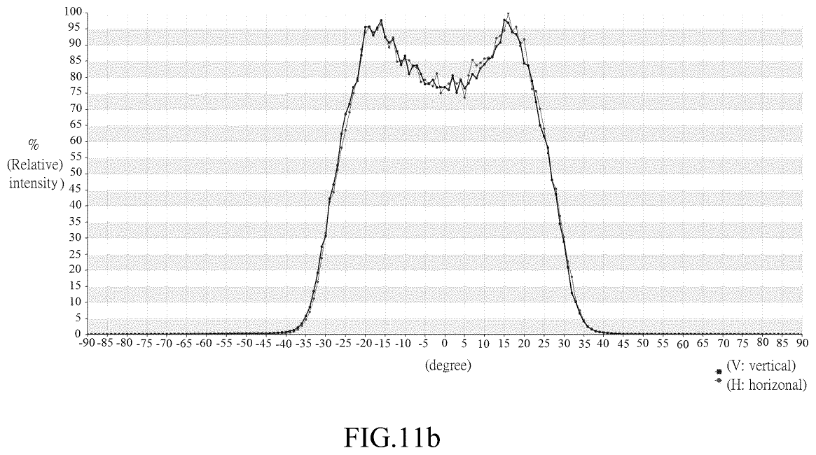

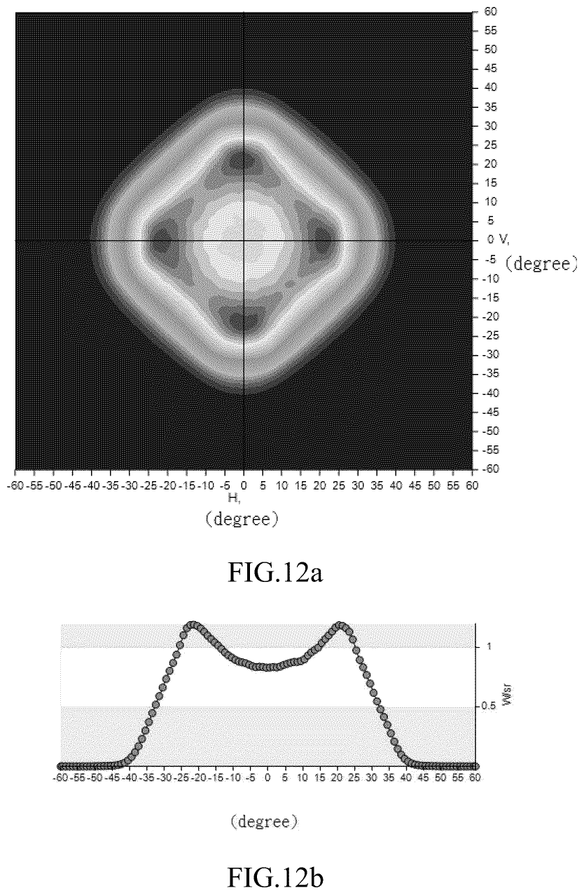

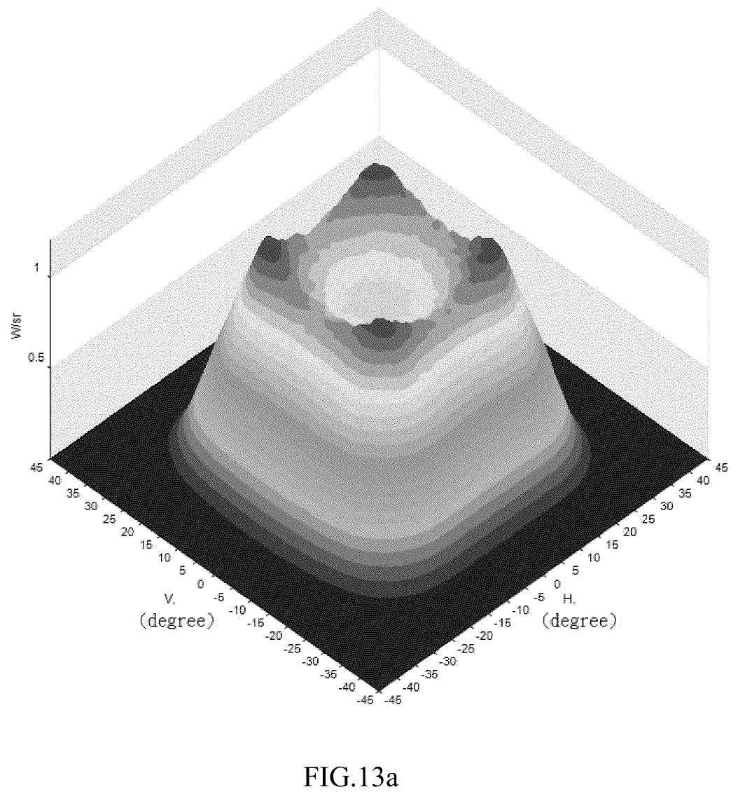

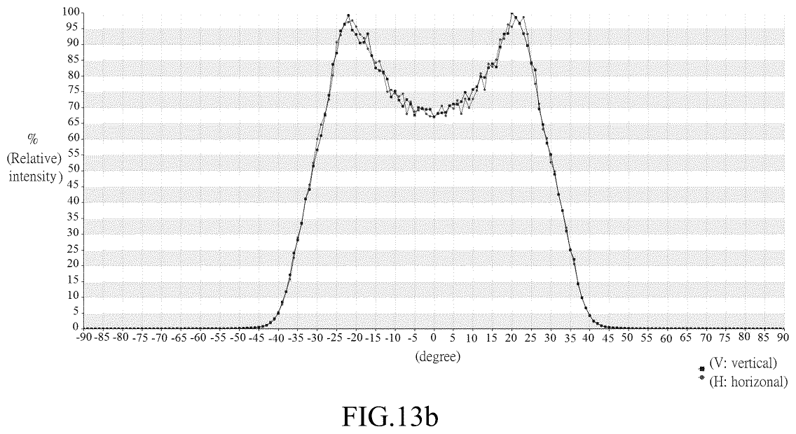

According to the light emitting device in other embodiments of the present disclosure, the first embodiment: Lighttools software is used to simulate the beam angle & light shape; parameter conditions are: (a) curvature: 40, (b) curvature coefficient (k): −1.30, (c) illumination profile: square, (d) light intensity angle of FOI (H&V axis): 30deg, (e) light intensity angle of FOI (Diagonal axis): 46deg, (f) working distance=1.35 mm, (g) the width of the spherical surface body is D, wherein D=0.038 mm. FIG. 10a and FIG. 10b are 2D light intensity diagrams of FOI (H&V axis) simulated by the Lighttools software of the light emitting device according to the first embodiment of the present disclosure. FIG. 11a and FIG. 11b are 3D light intensity diagrams of FOI (H&V axis) simulated by Lighttools software of the light emitting device according to the first embodiment of the present disclosure. FIG. 12a and FIG. 12b are 2D light intensity diagrams of FOI (Diagonal axis) simulated by the Lighttools software of the light emitting device according to the first embodiment of the present disclosure. FIG. 13a and FIG. 13b are 3D light intensity diagrams of FOI (Diagonal axis) simulated by the Lighttools software of the light emitting device according to the first Embodiment of the present disclosure.

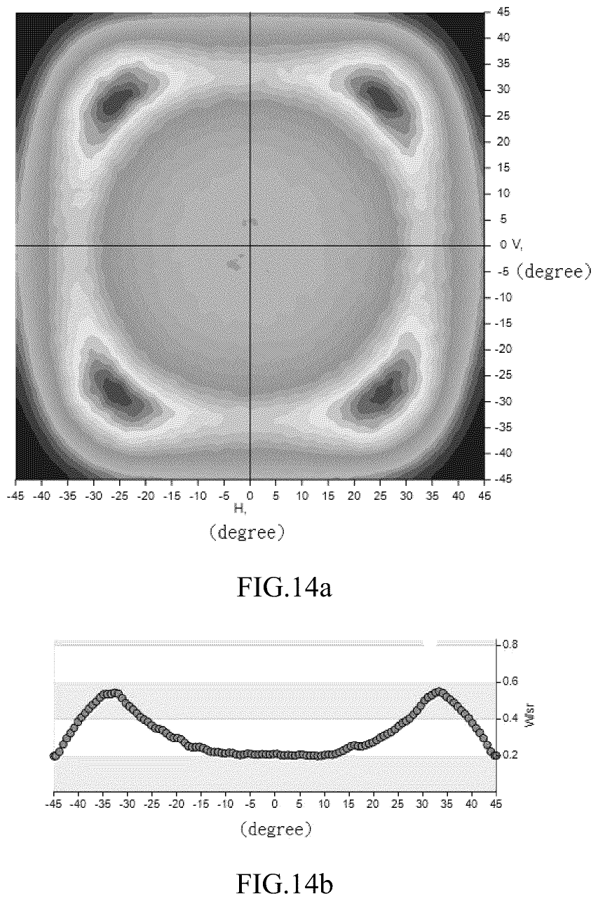

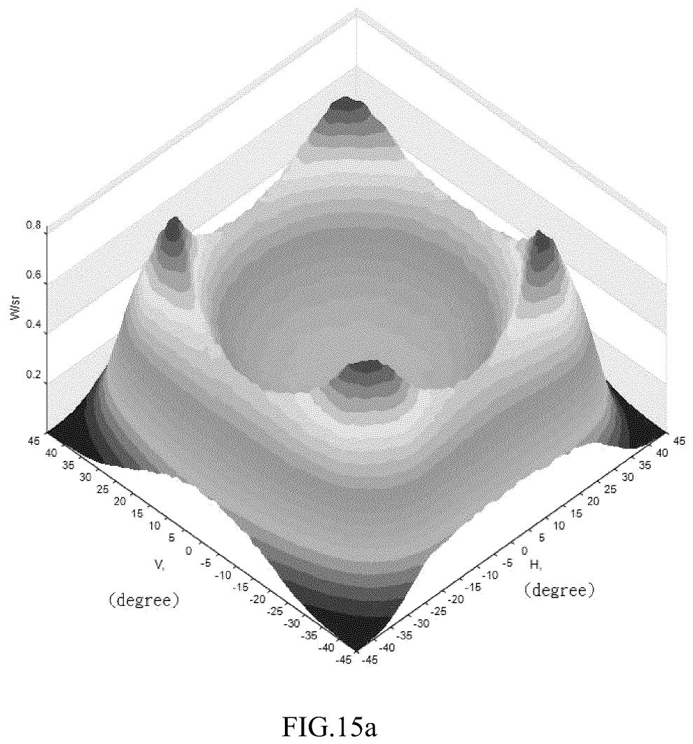

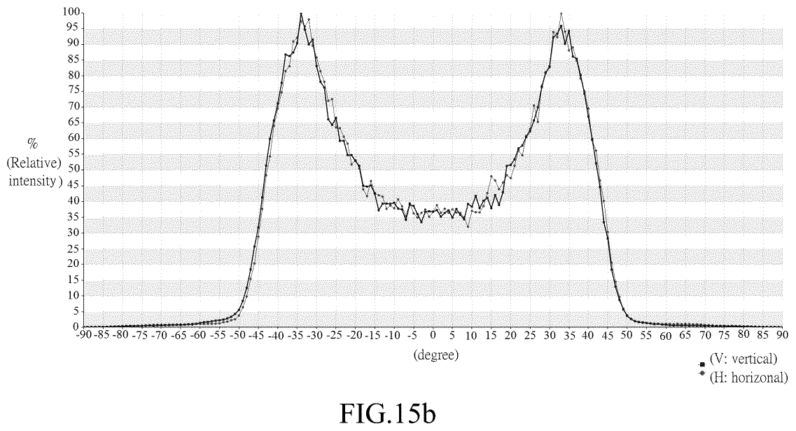

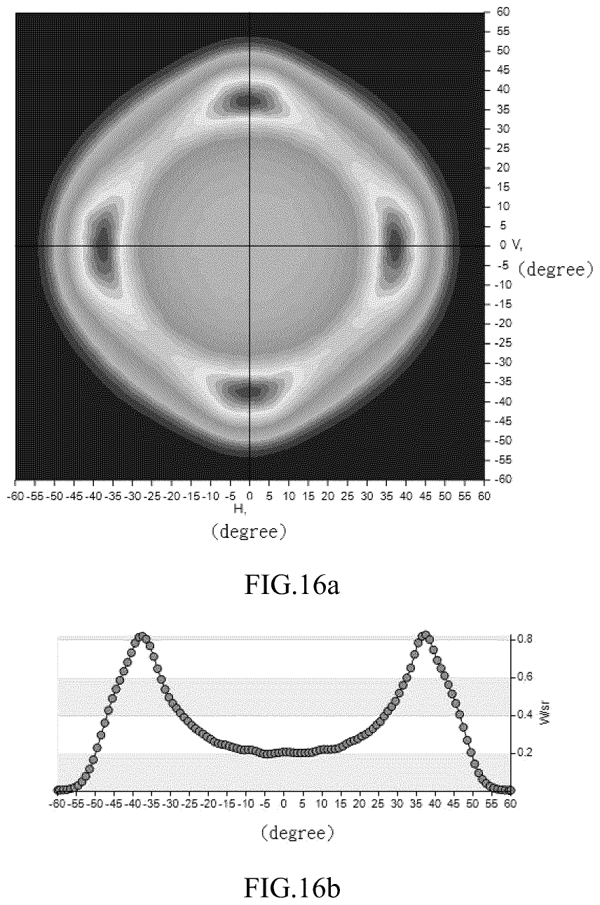

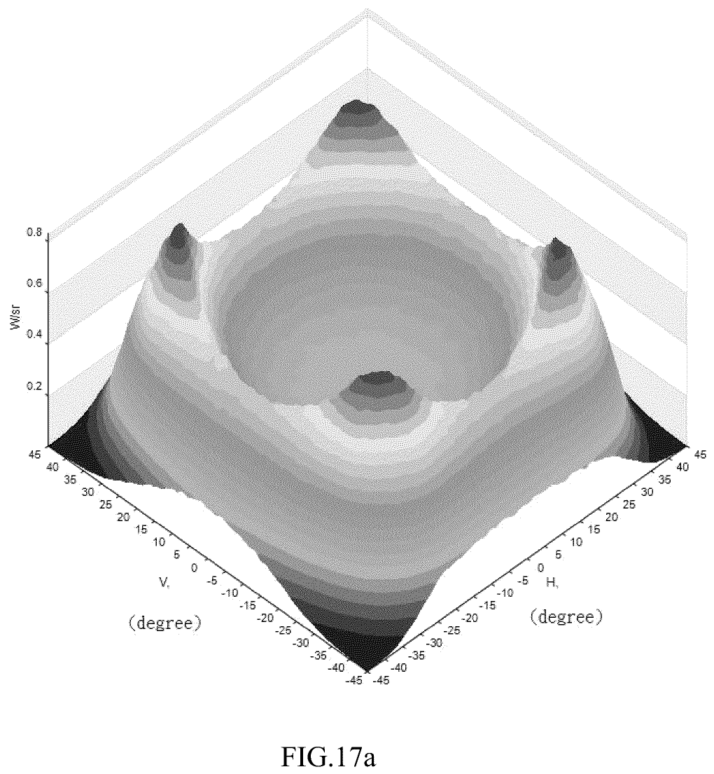

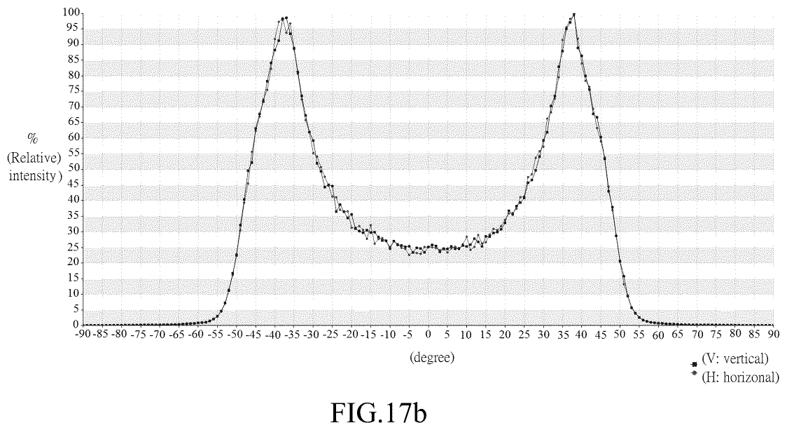

According to the light emitting device in other embodiments of the present disclosure, the second embodiment: Lighttools software is used to simulate the beam angle & light shape; parameter conditions are: (a) curvature: 85, (b) curvature coefficient (k): −1.30, (c) illumination profile: square, (d) light intensity angle of FOI (H&V axis): 68deg., (e) light intensity angle of FOI (Diagonal axis): 76deg., (f) working distance=1.35 mm, (g) the width of the spherical surface body is D, wherein D=0.038 mm. FIG. 14a and FIG. 14b are 2D light intensity diagrams of FOI (H&V axis) simulated by the Lighttools software of the light emitting device according to the second embodiment of the present disclosure. FIG. 15a and FIG. 15b are 3D light intensity diagrams of FOI (H& V axis) simulated by Lighttools software of the light emitting device according to the second embodiment of the present disclosure. FIG. 16a and FIG. 16b are 2D light intensity diagrams of FOI (Diagonal axis) simulated by the Lighttools software of the light emitting device according to the second embodiment of the present disclosure. FIG. 17a and FIG. 17b are 3D light intensity diagrams of FOI (Diagonal axis) simulated by the Lighttools software of the light emitting device according to the second Embodiment of the present disclosure.

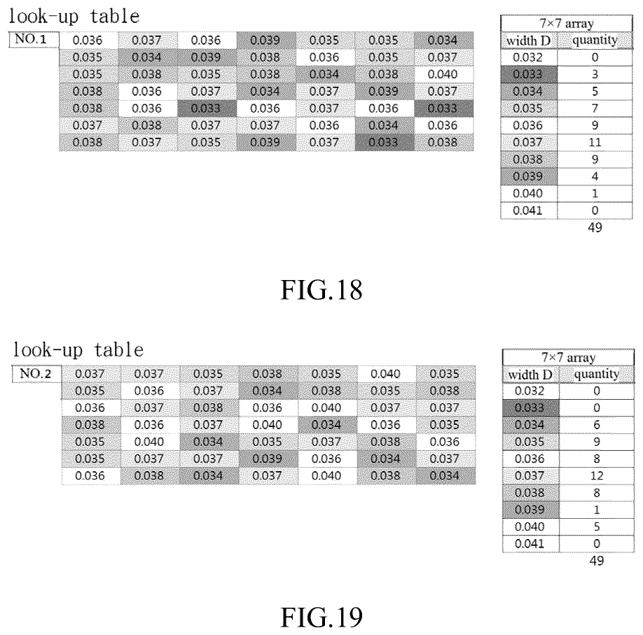

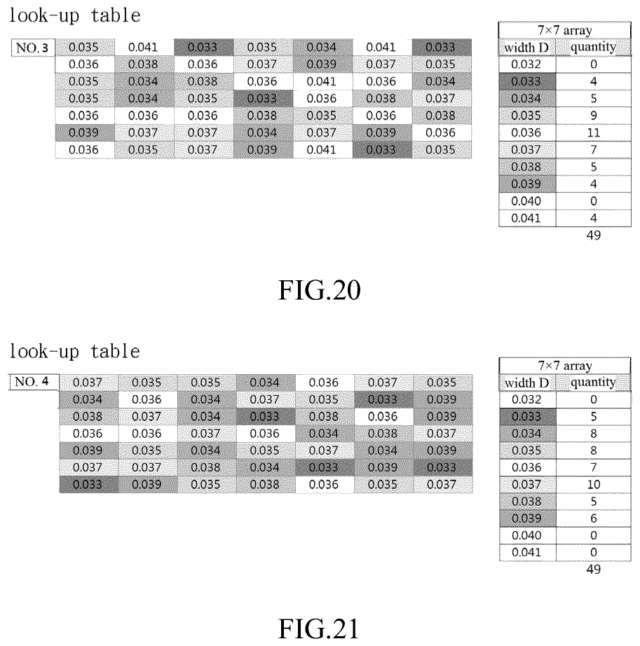

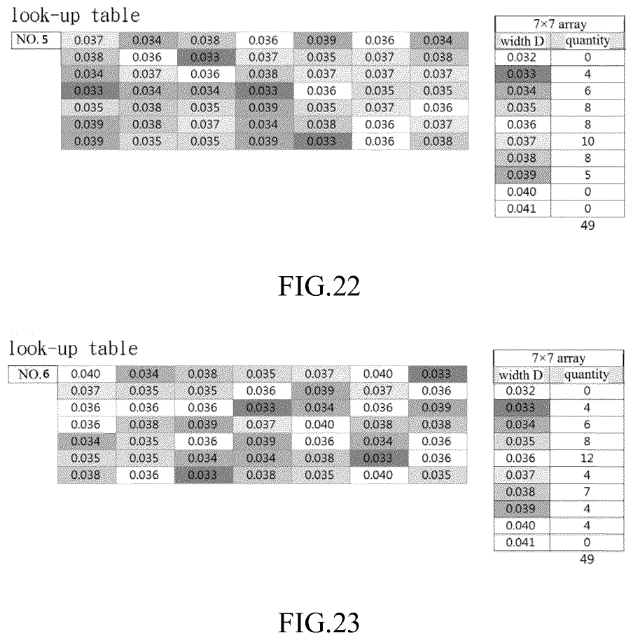

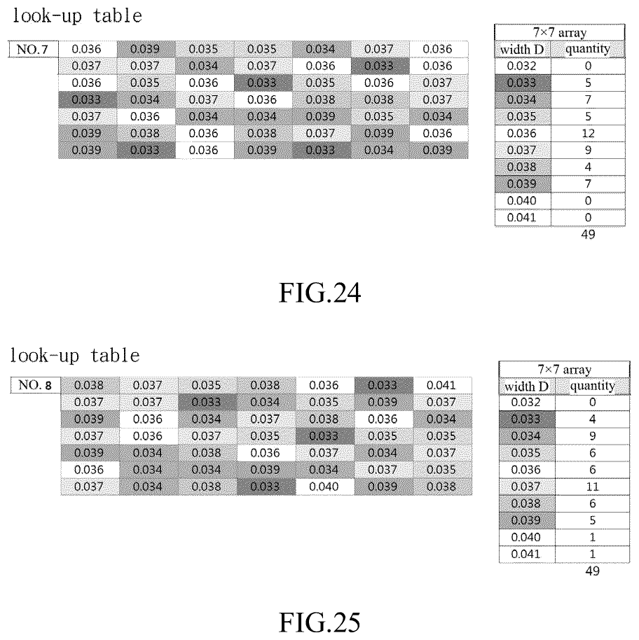

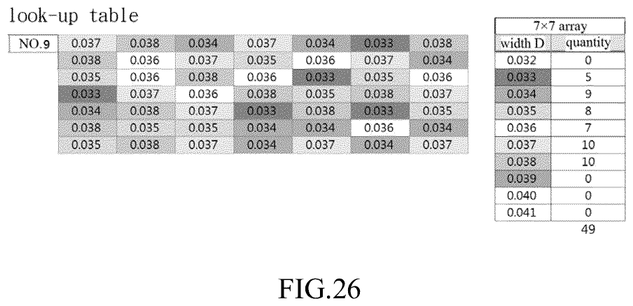

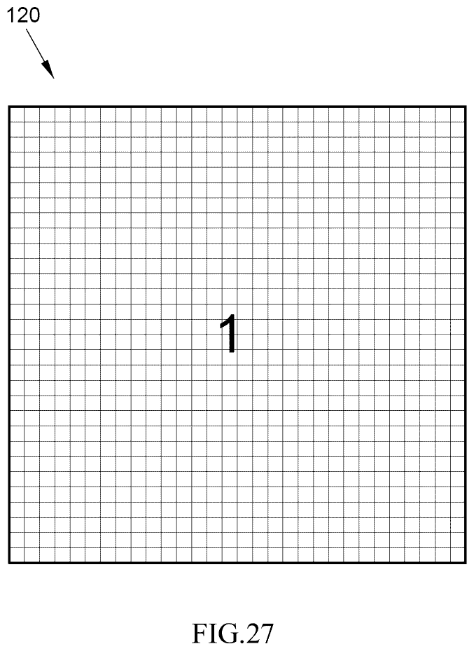

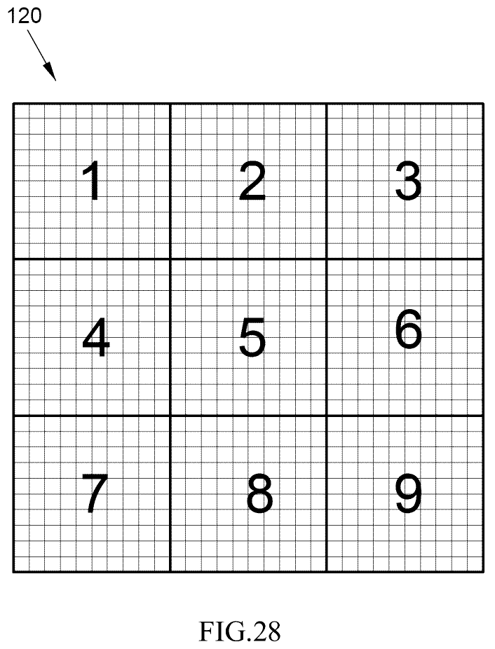

FIG. 18 to FIG. 26 are nine lookup tables (NO. 1 to NO. 9) based on the width D value of a plurality of spherical surface bodies of the present disclosure. FIG. 27 is a schematic diagram showing that spherical surface bodies are arranged in an array manner of a single area with an irregular Gaussian distribution according to the width D of a lookup table of the present disclosure. For example, the spherical surface bodies 120 are arranged in an array manner of a single area with an irregular Gaussian distribution according to the width D value of the lookup table (No. 1). FIG. 28 is a schematic diagram showing that spherical surface bodies the spherical surface bodies are arranged in an array manner of a 3×3 nine-area with an irregular Gaussian distribution according to the width D of lookup tables of the present disclosure. For example, the spherical surface bodies 120 are arranged in an array manner of a 3×3 nine-area (i.e., a nine-square grid) with an irregular Gaussian distribution according to the width D value of the lookup tables (NO. 1 to NO. 9). The width D of the spherical surface body can be between 0.034 and 0.042 mm.

In view of the above, the foregoing descriptions are merely preferred embodiments of technical means adopted by the present disclosure to solve the problem, but are not intended to limit the scope of the embodiments of the present disclosure. That is, all equivalent changes and modifications made in accordance with the scope of the patent application of the present disclosure or made in accordance with the scope of the patent of the present disclosure fall within the scope of the patent of the present disclosure.

What is claimed is:

1. A light emitting device, defined with a source side and an object sid and comprising:
a first base;
a first outer cap disposed on the first base and comprising es a first opening region;
a first optical lens disposed in the first opening region and having a source-side surface and an object-side surface, wherein the source-side surface includes a plurality of spherical surface bodies; and
an infrared light source disposed on the first base, wherein light of the infrared light source passes through the spherical surface bodies on the source-side surface of the first optical lens, so as to cause the light to produce a predetermined shape;
wherein each spherical surface body has a maximum thickness H along an X-axis, and a width D along a Y-axis, and the following condition is satisfied: D=3H; and
wherein the surface type of each spherical surface body is a quadratic surface, a vertex curvature is c, a curvature radius is r=√(X∧2+Y∧2), a conic constant is k, and the following formula for spherical surface is satisfied: Z=cr∧2/{1√[1−(1+k)c∧2r∧2]}, that is
$$z = \frac{{cr}^{2}}{1 + \sqrt{1 - ( 1 + k ) {c}^{2} {r}^{2}}} .$$

2. The light emitting device according to claim 1, wherein the spherical surface bodies are arranged on the source-side surface in an array manner.

3. The light emitting device according to claim 1, wherein a density of the spherical surface bodies is that there are N spherical surface bodies in the effective area of 1.0 mm*1.0 mm, N≤625.

4. The light emitting device according to claim 1, wherein the first optical lens is made of plastic material, and the refractive index (Nd) of the first optical lens is between 1.52 and 1.68.

5. The light emitting device according to claim 1, wherein a width D of the spherical surface body is between 0.034 and 0.042 mm.

6. The light emitting device according to claim 5, wherein the spherical surface bodies are arranged in an array manner with an irregular Gaussian distribution.

7. The light emitting device according to claim 6, wherein the spherical surface bodies are arranged in an array manner of a single area with an irregular Gaussian distribution according to the width D of a lookup table.

8. The light emitting device according to claim 6, wherein the spherical surface bodies are arranged in an array manner of a 3×3 nine-area with an irregular Gaussian distribution according to the width D of a lookup table.

9. The light emitting device according to claim 1, wherein a top view of the spherical surface body is square, rectangular, circular or elliptical, or the spherical surface body is hemispherical.

10. The light emitting device according to claim 1, wherein the vertex curvature of the spherical surface body is between 45 and 80.

11. The light emitting device according to claim 1, wherein the conic constant of the spherical surface body is between −1.0 and −2.5.

12. An optical ranging module, comprising:
a light emitting device, defined with a source side and an object sid and comprising:
a first base;
a first outer cap disposed on the first base and comprising es a first opening region;
a first optical lens disposed in the first opening region and having a source-side surface and an object-side surface, wherein the source-side surface includes a plurality of spherical surface bodies; and
an infrared light source disposed on the first base, wherein light of the infrared light source passes through the spherical surface bodies on the source-side surface of the first optical lens, so as to cause the light to produce a predetermined shape; and
a light receiving device comprising a second base, a second outer cap, a second optical lens and a photosensitive element, wherein the second outer cap is disposed on the second base and comprises a second opening region, the second optical lens is disposed in the second opening region, and the photosensitive element is disposed on the second base;
wherein the first base and the second base are integrally formed, and the first outer cap and the second outer cap are integrally formed;
wherein each spherical surface body has a maximum thickness H along an X-axis, and a width D along a Y-axis, and the following condition is satisfied: D=3H; and
wherein the surface type of each spherical surface body is a quadratic surface, a vertex curvature is c, a curvature radius √(X∧2+Y∧2) is r, a conic constant is k, and the following formula for spherical surface is satisfied: Z=cr∧2/{1√[1−(1+k)c∧2r∧2]}, that is
$$z = \frac{{cr}^{2}}{1 + \sqrt{1 - ( 1 + k ) {c}^{2} {r}^{2}}} .$$

13. The optical ranging module according to claim 12, wherein the spherical surface bodies are arranged on the source-side surface in an array manner.

14. The optical ranging module according to claim 12, wherein a density of the spherical surface bodies is that there are N spherical surface bodies in the effective area of 1.0 mm*1.0 mm, N≤625.

15. The optical ranging module according to claim 12, wherein the first optical lens is made of plastic material, and the refractive index (Nd) of the first optical lens is between 1.52 and 1.68.

16. The optical ranging module according to claim 12, wherein a width D of the spherical surface body is between 0.034 and 0.042 mm.

17. The optical ranging module according to claim 16, wherein the spherical surface bodies are arranged in an array manner with an irregular Gaussian distribution.

18. The optical ranging module according to claim 12, wherein a top view of the spherical surface body is square, rectangular, circular or elliptical, or the spherical surface body is hemispherical.

19. The optical ranging module according to claim 12, wherein the vertex curvature of the spherical surface body is between 45 and 80.

20. The optical ranging module according to claim 12, wherein the conic constant of the spherical surface body is between −1.0 and −2.5.
